(19) United States
(12) Patent Application Publication
(10) Pub. No.: US 2025/0192763 A1
(43) Pub. Date: Jun. 12, 2025

(54) DEVICES AND SYSTEMS FOR SAMPLING PULSE AMPLITUDE MODULATION SIGNALS WITH REDUCED KICKBACK NOISE

(71) Applicant: Advanced Micro Devices, Inc., Santa Clara, CA (US)

(72) Inventors: Raghavendra Rukmani Gowrishankar, Bengaluru (IN); Kamlesh Satyadev Singh, Bengaluru (IN)

(73) Assignee: Advanced Micro Devices, Inc., Santa Clara, CA (US)

(21) Appl. No.: 18/312,399

(22) Filed: May 4, 2023

(51) Int. Cl. H03K 5/1252; H03K 5/02; H03M 7/16

(52) U.S. Cl. CPC H03K 5/1252; G11C 27/02; H03K 5/02; H03M 1/1245; H03M 7/165

(57) ABSTRACT

The disclosed device can include a dual-tail sampler. The dual-tail sampler can include a first stage with an input pair, a cross-coupled load circuit, a precharge device between drain nodes of the input pair, and at least one pass-gate switch between the input pair and the cross-coupled load circuit. Various other devices and systems are also disclosed.

### BACKGROUND

Graphics processing units (GPUs) have been increasing in performance, such as by increasing data signal speeds, to meet increased real-time graphics processing demands. Certain techniques for increasing data signal speeds include using multilevel signaling formats. For example, rather than using two voltage levels (e.g., a high voltage level for bit “1” and a low voltage level for bit “0”), an architecture such as Pulse Amplitude Modulation 4-level (PAM 4) architecture can use four different voltage levels to correspond to two bits (e.g., “00,” “01,” “10,” and “11”). Such schemes can be prone to signal errors (e.g., from reduced noise tolerance from dividing a voltage range into four levels) and therefore can utilize samplers for error analysis/correction. However, the samplers themselves can introduce noise.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 is a diagram of an example system error receiver with pulse amplitude modulation signal samplers.

FIG. 2 is a diagram of an additional example system error receiver with pulse amplitude modulation signal samplers.

FIG. 3 is a diagram of an example system error receiver with pulse amplitude modulation signal samplers with dual-edge clocking.

FIG. 4 is a diagram of an example system error receiver with pulse amplitude modulation signal samplers with decision-based sampling.

FIG. 5 is a diagram of an example dual-tail sampler.

FIG. 6 is a diagram of an additional example dual-tail sampler.

FIG. 7 is a diagram of an example dual-tail sampler with pass-gate switch.

FIG. 8 is a graph showing kickback noise in an example sampling architecture.

FIG. 9 is a graph showing kickback noise in another example sampling architecture.

FIG. 10 is a graph showing kickback noise in another example sampling architecture.

FIG. 11 is a graph showing kickback noise in another example sampling architecture.

FIG. 12 is a graph showing kickback noise in another example sampling architecture.

FIG. 13 is a graph showing kickback noise in another example sampling architecture.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to devices and systems for sampling pulse amplitude modulation signals with reduced kickback noise. Kickback noise in a circuit can potentially cause any of a variety of issues, including signal distortion, timing errors, voltage spikes, and reduced system bit error rate (BER). Kickback noise due to sampling in a pulse amplitude modulation architecture (e.g., a Pulse Amplitude Modulation 4-level (PAM 4) architecture) can be high as multiple samplers can operate simultaneously. The devices and systems described herein can reduce kickback noise and/or power consumption. For example, a dual-tail sampler can reduce kickback by gating a cross-coupled load circuit using clock gating (CLK) switches. Additionally or alternatively, a dual-tail sampler can improve speed and/or reduce kickback noise by creating a feedback connection for p-channel metal-oxide-semiconductor field-effect transistor (PMOS) load latch transistors to the drain nodes of the input pair.

Furthermore, devices and systems described herein can include the use of three dual-tail samplers for sampling a PAM 4 signal (e.g., as part of a PAM 4 error receiver). Instead of the three samplers always operating simultaneously, the operation of the three samplers can be at least partially decoupled. For example, the high sampler can operate on the rising edge of the clock while the middle and low samplers can operate on the falling edge of the clock. Avoiding simultaneous operation of all three samplers can reduce kickback noise. In another example, the middle and low samplers can be clock-gated such that they only operate if the high sampler output is ‘1’ (indicating, e.g., a specific two-bit encoding, irrespective of the output of the other two samplers—such as a “no error” state).

In one implementation, a dual-tail sampler includes a first stage including an input pair, a cross-coupled load circuit, a precharge device between drain nodes of the input pair; and at least one pass-gate switch between the input pair and the cross-coupled load circuit.

In some examples, the at least one pass-gate switch comprises a pair of complementary pass-gate switches. In some examples, the cross-coupled load circuit is connected to drain nodes of the input pair rather than to output nodes of the first stage. In some examples, the first stage comprises an amplification stage. In some examples, the dual-tail sampler includes a precharge device connected between drain nodes of the input pair.

In some examples, the dual-tail sampler further includes a second stage. In some examples, the second stage includes an amplification stage. In some examples, the dual-tail sampler of claim 6, further includes a set-reset latch that encodes a sampled signal from the second stage as a bit.

In one implementation, a device includes a high dual-tail sampler, a middle dual-tail sampler, and a low dual-tail sampler. The high, middle, and low dual-tail samplers are configured to collectively sample a Pulse Amplitude Modulation 4-level (PAM 4) signal, and the high, middle, and low dual-tail samplers are configured to operate at least partially asynchronously with each other.

In some examples, the high, middle, and low dual-tail samplers are configured to operate at least partially asynchronously by one of the high, middle, and low dual-tail samplers being clocked using a first clock phase and a remaining two of the high, middle, and low dual-tail samplers being clocked using a second clock phase complementary to the first clock phase. In some examples, the high, middle, and low dual-tail samplers are configured to operate at least partially asynchronously by clock gating two of the high, middle, and low dual-tail samplers when the remaining sampler has a predetermined output. In some examples, the remaining sampler comprises the high sampler.

In some examples, at least one of the high, middle, and low dual-tail samplers includes a first stage includes an input pair, a cross-coupled load circuit, a precharge device between drain nodes of input pair, and at least one pass-gate switch between the input pair and the cross-coupled load circuit. In some examples, the at least one pass-gate switch comprises a pair of complementary pass-gate switches. In some examples, the cross-coupled load circuit is connected to drain nodes of the input pair rather than to output nodes of the first stage. In some examples, the first stage comprises an amplification stage. In some examples, the device further includes a precharge device connected between drain nodes of the input pair.

In one implementation, a system includes an error receiver that receives a PAM 4 error signal, the error receiver including a high dual-tail sampler, a middle dual-tail sampler, and a low dual-tail sampler, each of which receive the PAM 4 error signal, and each of which include a first stage including an input pair, a cross-coupled load circuit, a precharge device between drain nodes of the input pair, and at least one pass-gate switch between the input pair and the cross-coupled load circuit. The system also includes a thermometer-to-binary device that converts outputs of the high, middle, and low dual-tail samplers into a two-bit error code.

In some examples, one of the high, middle, and low dual-tail samplers is clocked using a first clock phase and a remaining two of the high, middle, and low dual-tail samplers is clocked using a second clock phase complementary to the first clock phase. In some examples, a given output of a selected dual-tail sampler of the high, middle, and low dual-tail samplers maps to a given error class in the two-bit error code irrespective of signals from a remaining two dual-tail samplers, and the two remaining dual-tail samplers are clock gated when the selected dual-tail sampler has the given output.

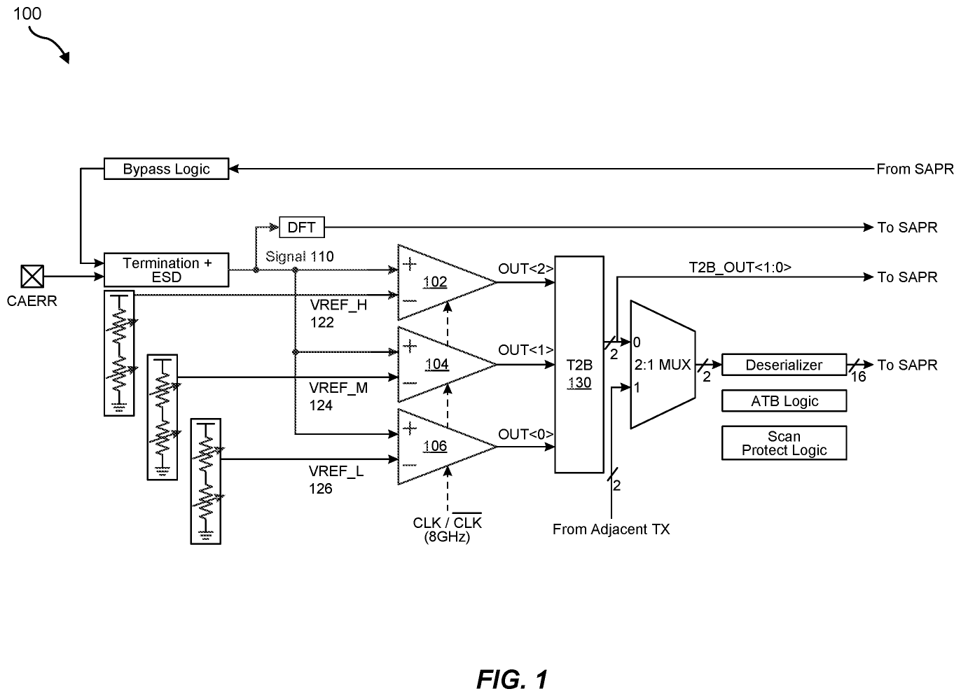

FIG. 1 is a diagram of an example system error receiver 100 with samplers 102, 104, and 106.

The devices and systems described herein can include, interoperate with, and/or be incorporated into an error receiver, such as error receiver 100 (e.g., an address command error receiver for a graphics processing unit (GPU)). In some examples, one or more of the systems described herein can encode information of faithful data transmission into PAM 4 levels. By way of example, level 00 (−3 symbol) can indicate both a Cyclic Redundancy Check (CRC) error and a parity error, level 01 (−1 symbol) can indicate a parity error, level 10 (+1 symbol) can indicate a CRC error, and level 11 (+3 symbol) can indicate no error.

A PAM 4 based architecture can make use of three samplers (e.g., samplers 102, 104, and 106) to resolve the incoming input signal (e.g., signal 110). However, kickback noise can be aggravated by the continuous operation of samplers 102, 104, and 106. As used herein, the term “kickback noise” can refer to any noise (e.g., out-of-specification current or voltage fluctuations) that can interfere with one or more circuits and/or components (e.g., circuits that neighbor the origin of the kickback noise). In some examples, kickback noise from a device can be caused by a switch in a signal in and/or by the device.

Samplers 102, 104, and 106 can represent any suitable type of sampler. For example, samplers 102, 104, and 106 can represent dual-tail samplers. As shown in FIG. 1, reference voltages 122, 124, and 126 can be provided by respective voltage reference generator circuits. In one example, reference voltage 122 can represent a high voltage (“VREF_H”), reference voltage 124 can represent a medium voltage (“VREF_M”) and a reference voltage 126 can represent a low voltage (“VREF_L”). In one example, the reference voltages 122, 124, and 126 can be provided as the negative inputs to samplers 102, 104, and 106, respectively. A signal 110 (e.g., a PAM 4 signal, such as one carrying address command and/or data transmission error information) can be provided as the positive inputs to samplers 102, 104, and 106. Thus, samplers 102, 104, and 106 can sample the PAM 4 signal at different voltage levels.

In one example, signal 110 can arrive as +3, +1, −1, or −3 symbols. Sampler 102 can output (OUT<2>) ‘1’ for a +3 symbol and ‘0’ for the lower voltage signals. Sampler 104 can output (OUT<1>) ‘1’ for a +3 or +1 symbols and ‘0’ for the lower voltage signals. Sampler 106 can output (OUT<0>) ‘1’ for a +3, +1, or −1 symbols and ‘0’ for a ‘−3’ symbol. Thus, a PAM 4 signal of a +3 symbol can be sampled by samplers 102, 104, and 106, resulting in a collective signal of OUT<2:0>=‘111’. A thermometer-to-binary module (e.g., T2B 130) can convert and/or encode the three-bit collective output from the samplers as two bits: e.g., encoding ‘111’ as ‘10’, ‘011’ as ‘11’, ‘001’ as ‘01’, and ‘000’ as ‘00’.

However, kickback noise created by the simultaneous operation of samplers 102, 104, and 106 can negatively impact the performance of error receiver 100. For example, the kickback noise from samplers 102, 104, and 106 can distort the incoming PAM 4 signal, potentially causing errors in the sampling of signal 110 and the eventual encoding of signal 110 into a binary error code.

In some examples, error receiver 100 can include various other components and signals, including a command address error signal (CAERR), a module including a termination circuit and an electrostatic discharge protection circuit (Termination+ESD), a bypass logic component, a 2:1 multiplexer (2:1 MUX), a deserializer, an Analog Test Bus (ATB Logic), a scan protect logic, a loopback signal from an adjacent transmitter (Adjacent TX).

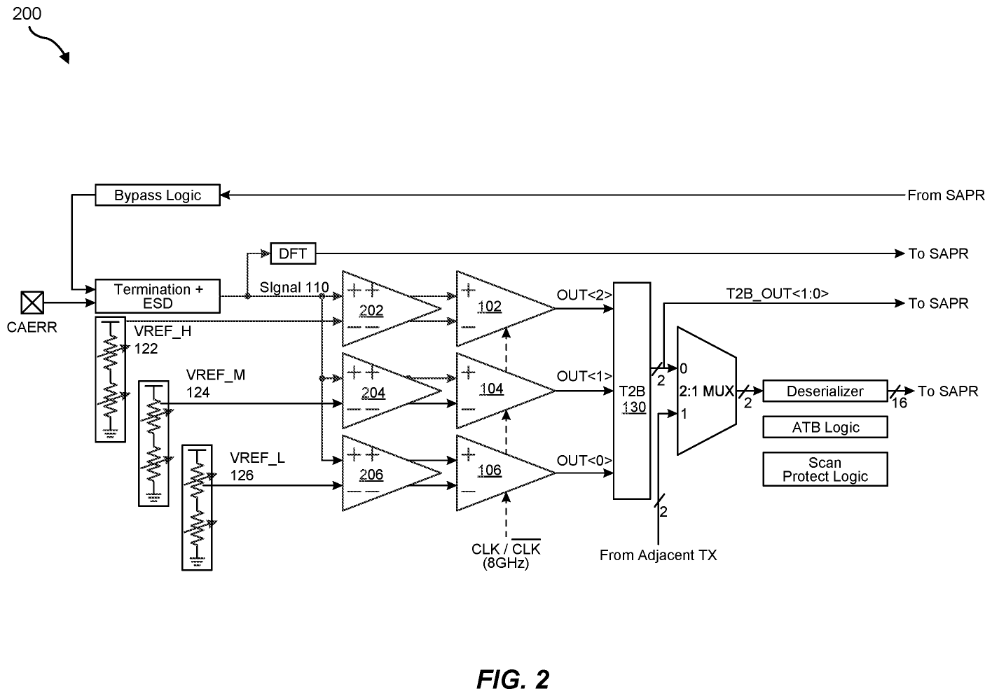

FIG. 2 is a diagram of an example error receiver 200. As shown in FIG. 2, error receiver 200 can be similar to error receiver 100 of FIG. 1, except that error receiver 200 includes three pre-amplifiers 202, 204, and 206 placed before samplers 102, 104, and 106. Thus, samplers 102, 104, and 106 can receive signal 110 and reference voltages 122, 124, and 126 via pre-amplifiers 202, 204, and 206 instead of directly. Pre-amplifiers 202, 204, and 206 can help to shield against kickback noise from samplers 102, 104, and 106 onto the rest of the circuit. However, pre-amplifiers 202, 204, and 206 can increase the power consumption of error receiver 200. In addition, pre-amplifiers 202, 204, and 206 can increase the input referred offset at signal 110.

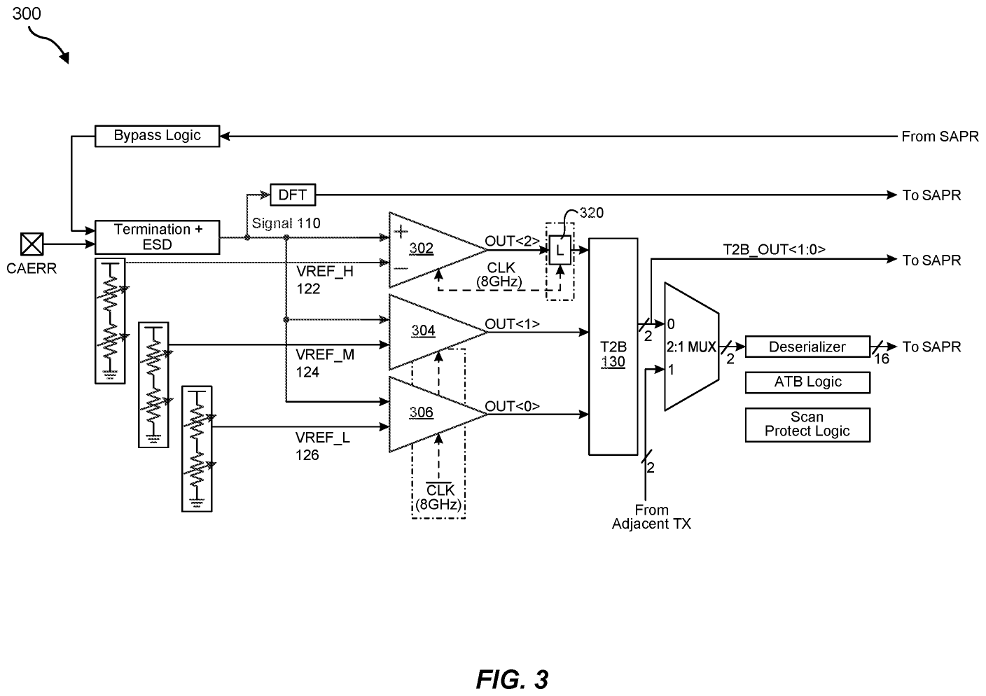

FIG. 3 is a diagram of an example system error receiver 300. As shown in FIG. 3, error receiver 300 can have architectural elements in common with error receiver 100 of FIG. 1. However, in contrast to dual-tail samplers 102, 104, and 106 of FIG. 1, dual-tail samplers 302, 304, and 306 can be configured to operate at least partially asynchronously. For example, dual-tail samplers 302, 304, and 306 can be configured to not all operate simultaneously. Instead, one of dual-tail samplers 302, 304, and 306 can be configured to operate on a different clock phase than the other two samplers. Thus, for example, dual-tail sampler 302 can operate on one clock phase (e.g., the rising edge of the clock) and dual-tail samplers 304 and 306 can operate on a complementary clock phase (e.g., the falling edge of the clock). Furthermore, a latch 320 can be placed between dual-tail sampler 302 and T2B 130 to maintain data integrity.

Kickback noise can be aggravated when all three dual-tail samplers 302, 304, and 306 are clocked on the same phase—and at least two samplers will experience a large differential voltage between their input pair devices. Thus, clocking dual-tail sampler 302 on a different clock phase than dual-tail samplers 304 and 306 can significantly mitigate kickback noise.

In addition, as will be explained in greater detail below, dual-tail samplers 302, 304, and/or 306 can have an internal configuration to reduce kickback noise.

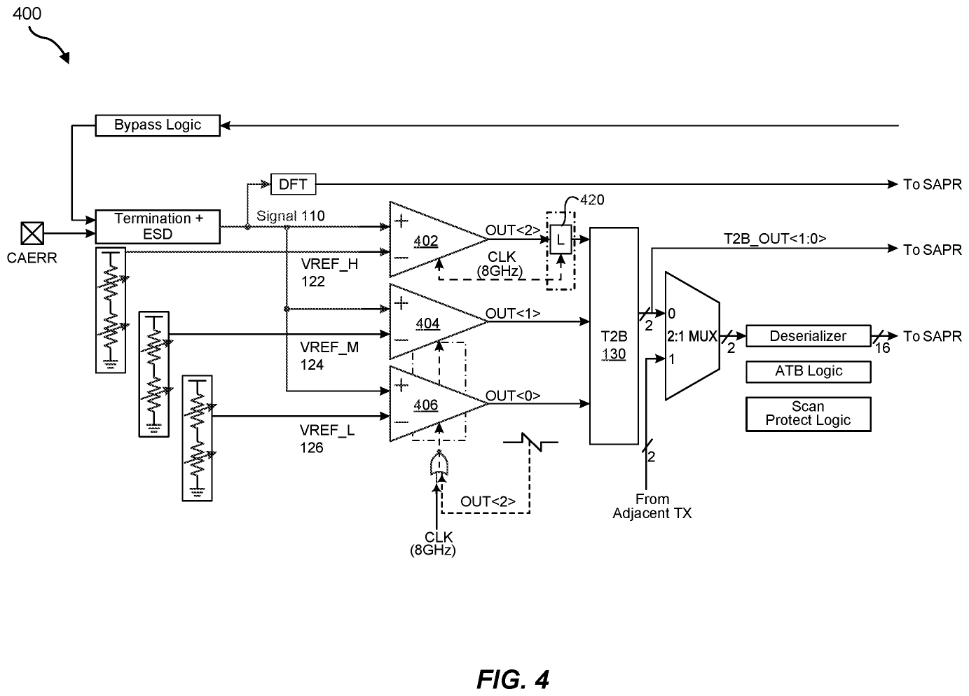

FIG. 4 is a diagram of an example system error receiver 400. As shown in FIG. 4, error receiver 400 can have architectural elements in common with error receiver 100 of FIG. 1. However, in contrast to dual-tail samplers 102, 104, and 106 of FIG. 1, dual-tail samplers 402, 404, and 406 can be configured to operate at least partially asynchronously. For example, dual-tail samplers 402, 404, and 406 can be configured to not all operate simultaneously. Instead, a selected dual-tail sampler can clock-gate the other dual-tail samplers on a predetermined output. For example, one or both of dual-tail samplers 404 and 406 can be clock-gated by the output of dual-tail sampler 402 (OUT<2>) (e.g., gated when dual-tail sampler 402 has a predetermined output). Thus, for example, when the output of dual-tail sampler 402 is ‘1’, dual-tail samplers 404 and 406 cannot operate, thereby avoiding kickback noise (and reducing power consumption). Because, as described earlier, a value of ‘1’ from dual-tail sampler 402 can always indicate a no error condition (e.g., all PAM 4 values corresponding to a ‘1’ in the high value can map to a two-bit binary value indicating “no error”), the outputs of dual-tail samplers 404 and 406 can be irrelevant when the output of dual-tail sampler 402 is ‘1’. As can be appreciated, the same principle can apply whenever an output of one dual-tail sampler is sufficient to distinguish a class of conditions (e.g., an error class, such as “no error” or a class of errors) such that, for the purposes of the broader system, the outputs of the remaining dual-tail samplers are irrelevant. Furthermore, a latch 420 can be placed between dual-tail sampler 402 and T2B 130 to maintain data integrity.

In addition, as will be explained in greater detail below, dual-tail samplers 402, 404, and/or 406 can have an internal configuration to reduce kickback noise.

In some examples, error receiver 400 can be used in a context in which an expected error rate is low. E.g., because error receiver 400 achieves improved performance when the PAM 4 signal indicates no error, error receiver 400 can be particularly suitable for scenarios in which the majority of time no error is indicated. Thus, for example, error receiver 400 can be suitable in some context as an address command error receiver for a GPU. In some examples, error receiver 400 can be part of a larger system in which a subsystem with a low error rate sends an error signal to error receiver 400. Examples of the low error rate include without limitation, an average error rate of 10% or lower, of 5% or lower, of 3% or lower, of 2% or lower, or of 1% or lower.

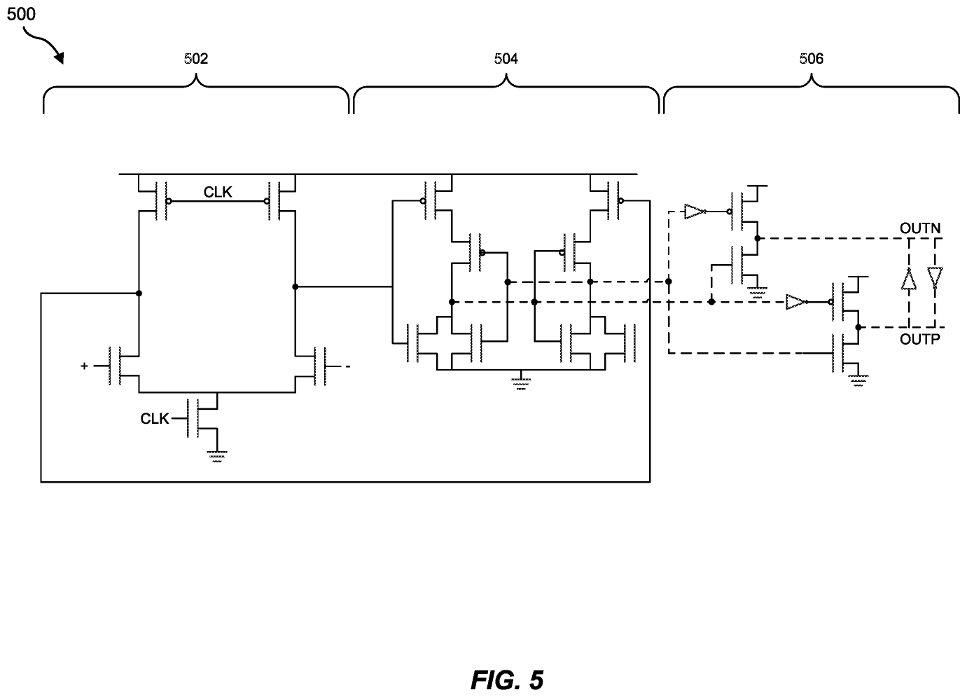

FIG. 5 is a diagram of an example dual-tail sampler 500. As shown in FIG. 5, dual-tail sampler 500 can include a first stage 502 (e.g., an amplification stage), a second stage (e.g., a rail-to-rail amplification stage) 504, and a set-reset latch 506. As can be seen in FIG. 5, sampler 500 can produce kickback noise from PMOS load devices in first stage 502 to the gates of the input pair.

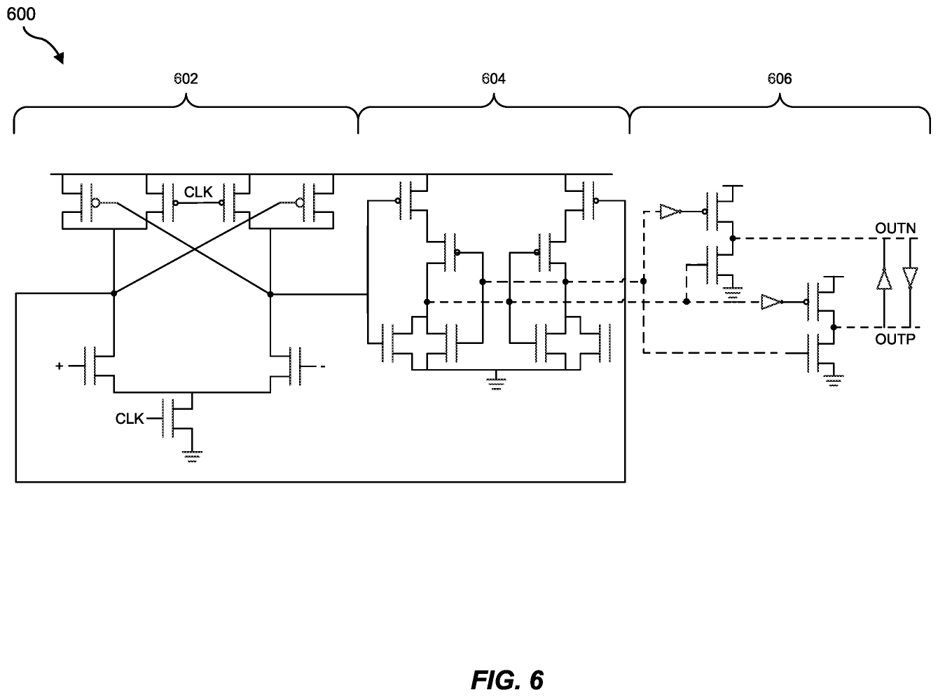

FIG. 6 is a diagram of an example dual-tail sampler 600. As shown in FIG. 6, dual-tail sampler 600 can include a first stage 602 (e.g., an amplification stage), a second stage (e.g., a rail-to-rail amplification stage) 604, and a set-reset latch 606. As can be seen in FIG. 6, sampler 600 can produce kickback noise from PMOS load devices in first stage 602 to the gates of the input pair.

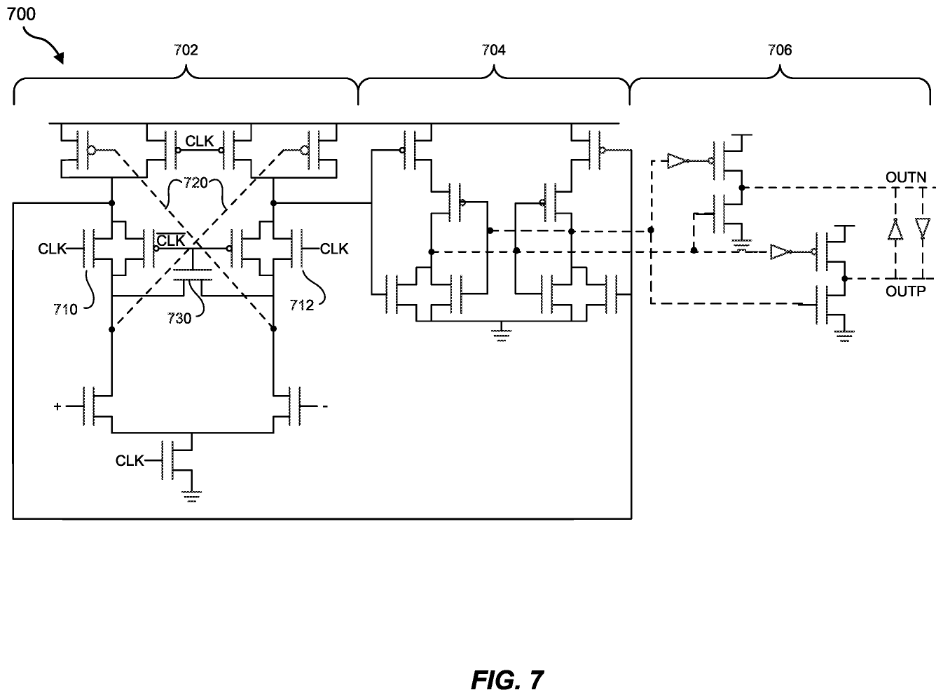

FIG. 7 is a diagram of an example dual-tail sampler 700. As shown in FIG. 7, dual-tail sampler 700 can include a first stage 702 (e.g., an amplification stage), a second stage (e.g., a rail-to-rail amplification stage) 704, and a set-reset latch 706. As can be seen in FIG. 7, sampler 700 can have some common architectural features with dual-tail samplers 500 and 600. For example, in first stage 702, sampler 700 can include an input pair, a cross-coupled load circuit, and PMOS load latch transistors. In addition, sampler 700 can include a pass-gate switch between the input pair and the cross-coupled load circuit. For example, sampler 700 can include a pair of complementary pass-gate switches, such as switches 710 and 712. In one example, switches 710 and 712 can be CLK switches. Switches 710 and 712 can gate kickback from the cross-coupled load circuit, shielding the input pair.

Furthermore, in some examples, dual-tail sampler 700 can include one or more connections from the cross-coupled load circuit to the drain nodes of the input pair (rather than, e.g., to output nodes of first stage 702. For example, dual-tail sampler 700 can include connections 720 from the cross-coupled load circuit to the drain nodes of the input pair. Connections 720 can reduce the regeneration period of sampler 700.

In addition, in some examples, dual-tail sampler 700 can include a precharge device connected between the drain nodes of the input pair. For example, dual-tail sampler 700 can include precharge device 730. In one example, precharge device 730 can be an n-channel metal-oxide-semiconductor field-effect transistor (NMOS). The presence of precharge device 730 can prevent inter-symbol interference (ISI) issues and/or memory issues (e.g., residual charge left on drain nodes of input pair after evaluation phase).

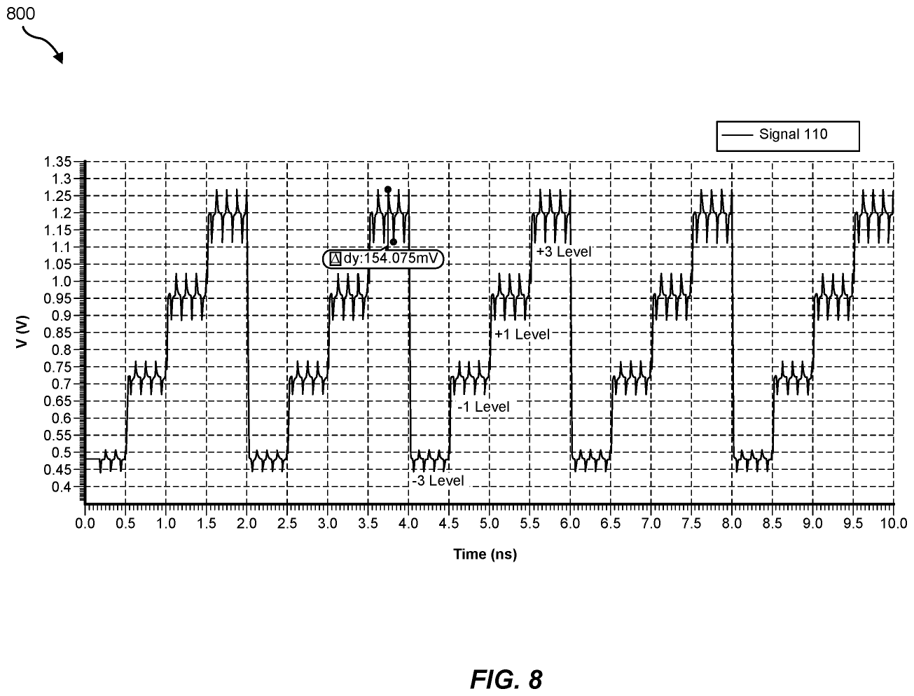

FIG. 8 is a graph 800 showing kickback noise in an example sampling architecture. For example, graph 800 can represent signal 110 from error receiver 100 as shown in FIG. 1, where samplers 102, 104, and 106 are instances of sampler 600 shown in FIG. 6. As can be seen in FIG. 8, graph 800 represents signal 110 for the various possible PAM 4 signals. In addition, graph 800 illustrates kickback noise experienced at the node preceding the samplers. As the input level of the PAM 4 signal increases (from −3, to −1, to +1, to +3), so does the degree of the kickback noise. At +3, the delta of the kickback noise is approximately 154 millivolts (mV), which is substantial in relation to the voltage difference of the different signal levels. In one example, graph 800 can represent a sampler current consumption of approximately 5.286 milliamperes (mA).

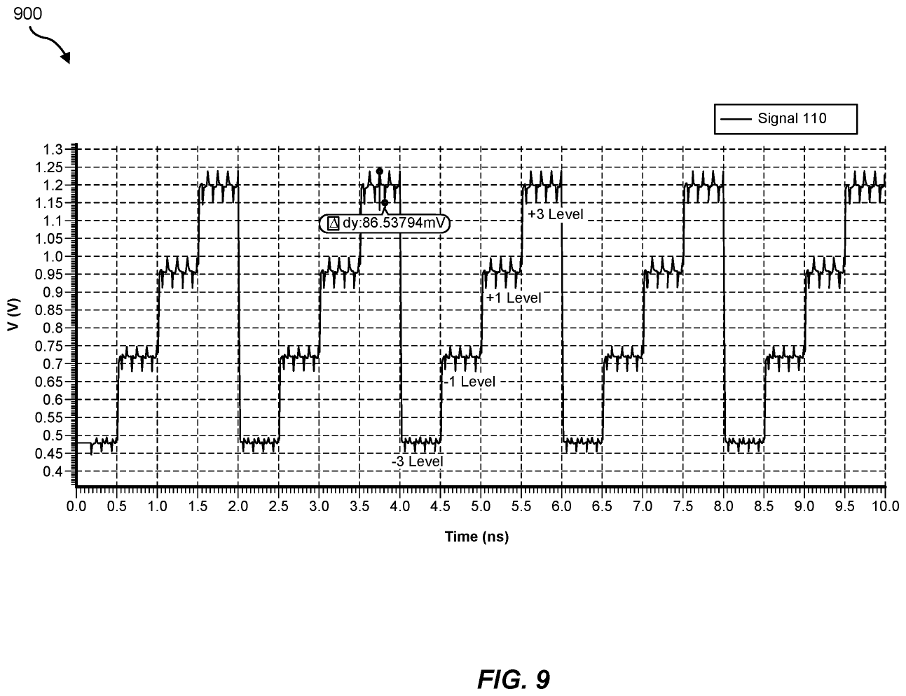

FIG. 9 is a graph 900 showing kickback noise in an example sampling architecture. For example, graph 900 can represent signal 110 from error receiver 100 as shown in FIG. 1, except where samplers 102, 104, and 106 are instances of sampler 700 shown in FIG. 7. As can be seen in FIG. 8, graph 900 represents signal 110 for the various possible PAM 4 signals. In addition, graph 900 illustrates kickback noise experienced at the node preceding the samplers. At the PAM 4 +3 signal, the delta of the kickback noise is approximately 84 millivolts (mV). In one example, graph 900 can represent a sampler current consumption of approximately 5.480 milliamperes (mA).

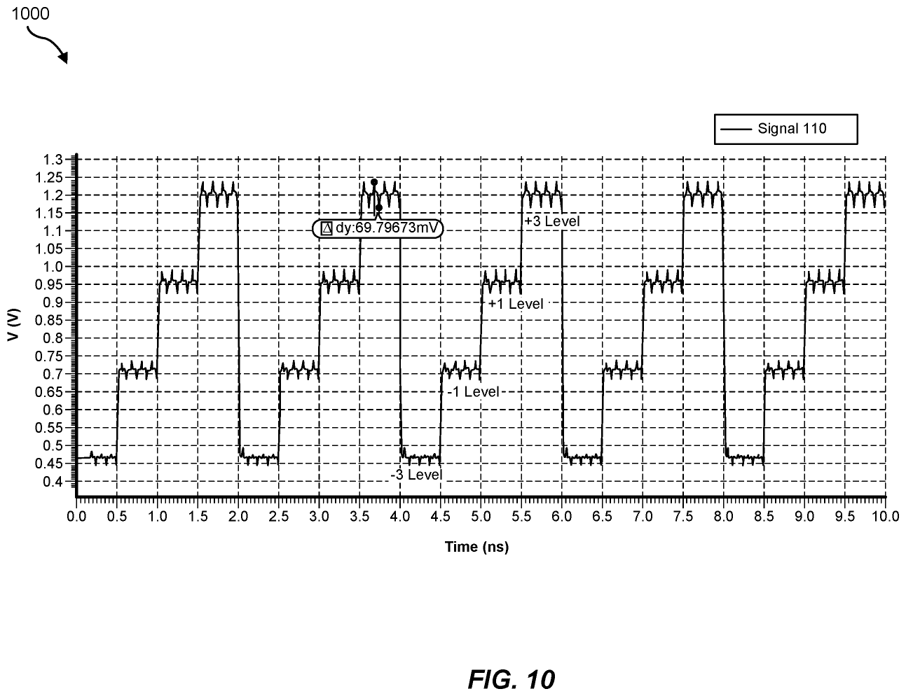

FIG. 10 is a graph 1000 showing kickback noise in another example sampling architecture. For example, graph 1000 can represent signal 110 from error receiver 300 as shown in FIG. 3, where samplers 302, 304, and 306 are instances of sampler 600 shown in FIG. 6. As can be seen in FIG. 10, graph 1000 represents signal 110 for the various possible PAM 4 signals. In addition, graph 1000 illustrates kickback noise experienced at the node preceding the samplers. At the PAM 4 signal level +3, the delta of the kickback noise is approximately 70 millivolts (mV). In one example, graph 1000 can represent a sampler current consumption of approximately 5.286 milliamperes (mA).

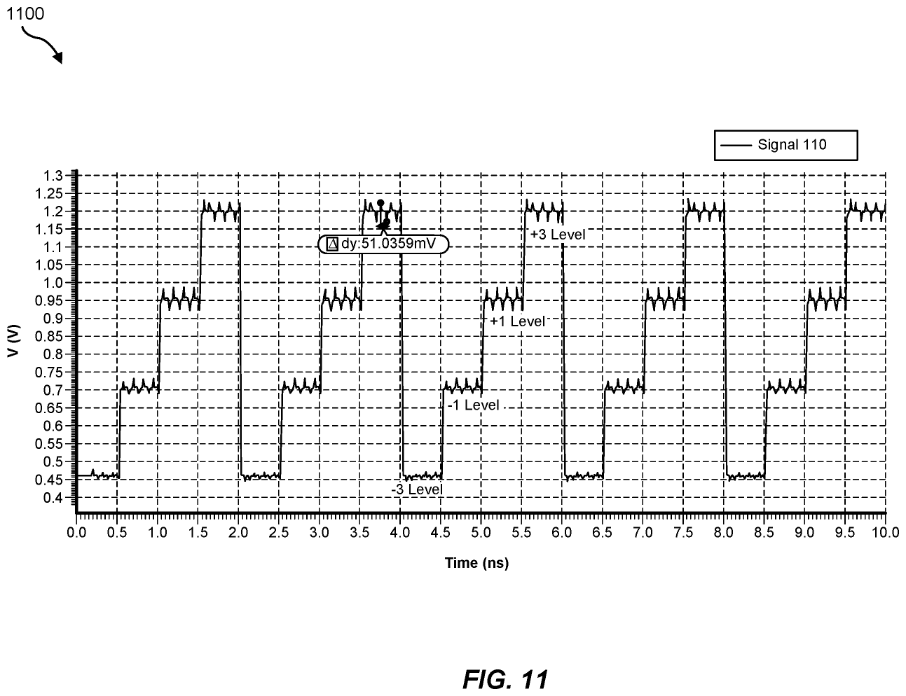

FIG. 11 is a graph showing kickback noise in another example sampling architecture. For example, graph 1100 can represent signal 110 from error receiver 400 as shown in FIG. 4, where samplers 402, 404, and 406 are instances of sampler 600 shown in FIG. 6. As can be seen in FIG. 11, graph 1100 represents signal 110 for the various possible PAM 4 signals. In addition, graph 1100 illustrates kickback noise experienced at the node preceding the samplers. At the PAM 4 signal level +3, the delta of the kickback noise is approximately 51 millivolts (mV). In one example, graph 1100 can represent a sampler current consumption of approximately 2.241 milliamperes (mA).

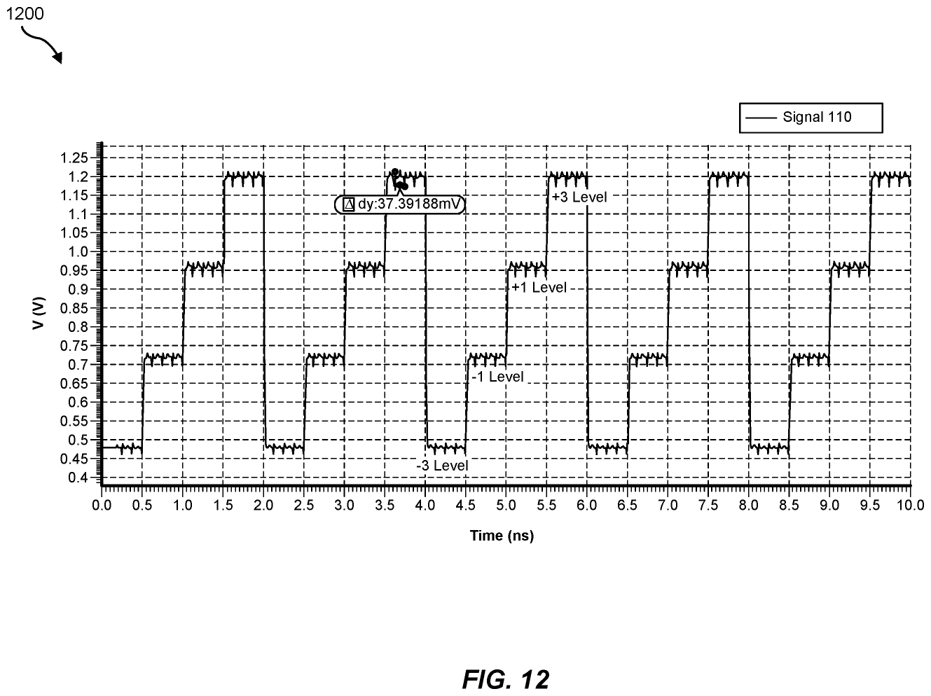

FIG. 12 is a graph 1200 showing kickback noise in another example sampling architecture. For example, graph 1200 can represent signal 110 from error receiver 300 as shown in FIG. 3, where samplers 302, 304, and 306 are instances of sampler 700 shown in FIG. 7. As can be seen in FIG. 12, graph 1200 represents signal 110 for the various possible PAM 4 signals. In addition, graph 1200 illustrates kickback noise experienced at the node preceding the samplers. At the PAM 4 signal level +3, the delta of the kickback noise is approximately 37 millivolts (mV). In one example, graph 1200 can represent a sampler current consumption of approximately 5.480 milliamperes (mA).

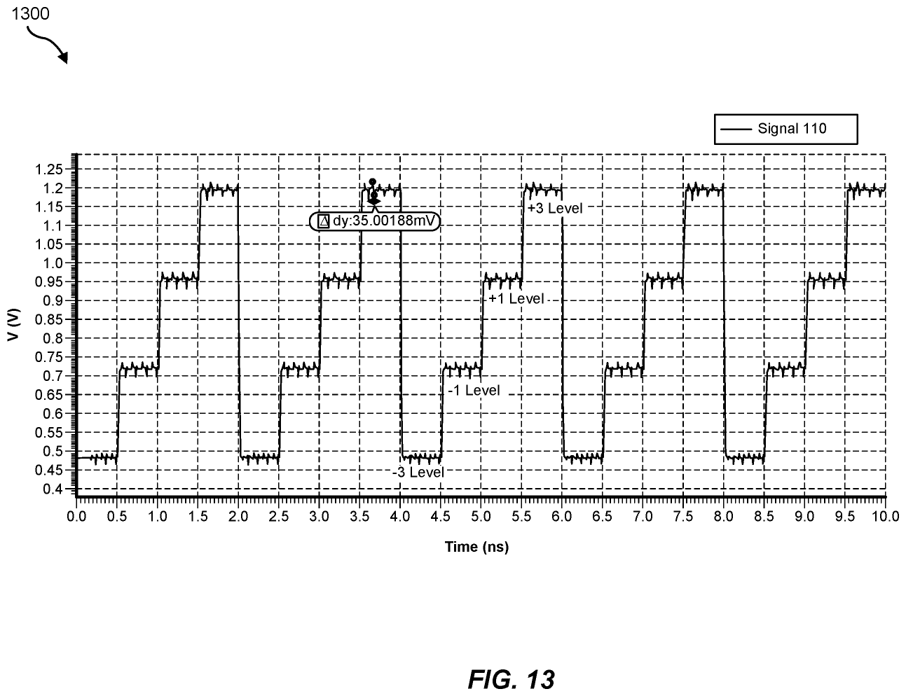

FIG. 13 is a graph 1300 showing kickback noise in another example sampling architecture. For example, graph 1300 can represent signal 110 from error receiver 400 as shown in FIG. 4, where samplers 402, 404, and 406 are instances of sampler 700 shown in FIG. 7. As can be seen in FIG. 13, graph 1300 represents signal 110 for the various possible PAM 4 signals. In addition, graph 1300 illustrates kickback noise experienced at the node preceding the samplers. At the PAM 4 signal level +3, the delta of the kickback noise is approximately 35 millivolts (mV). In one example, graph 1300 can represent a sampler current consumption of approximately 2.554 milliamperes (mA).

As can be appreciated from the foregoing, the devices and systems described herein can reduce kickback noise with little power cost and/or significant power savings, and little additional current consumption and/or significantly reduced current consumption.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A dual-tail sampler comprising:
a first stage comprising:
an input pair;
a cross-coupled load circuit;
a precharge device between drain nodes of the input pair; and
at least one pass-gate switch between the input pair and the cross-coupled load circuit.

2. The dual-tail sampler of claim 1, wherein the at least one pass-gate switch comprises a pair of complementary pass-gate switches.

3. The dual-tail sampler of claim 1, wherein the cross-coupled load circuit is connected to drain nodes of the input pair rather than to output nodes of the first stage.

4. The dual-tail sampler of claim 1, wherein the first stage comprises an amplification stage.

5. The dual-tail sampler of claim 1, further comprising a precharge device connected between drain nodes of the input pair.

6. The dual-tail sampler of claim 1, further comprising a second stage.

7. The dual-tail sampler of claim 6, wherein the second stage comprises an amplification stage.

8. The dual-tail sampler of claim 6, further comprising a set-reset latch that encodes a sampled signal from the second stage as a bit.

9. A device comprising:
a high dual-tail sampler;
a middle dual-tail sampler; and
a low dual-tail sampler;
wherein:
the high, middle, and low dual-tail samplers are configured to collectively sample a Pulse Amplitude Modulation 4-level (PAM 4) signal; and
the high, middle, and low dual-tail samplers are configured to operate at least partially asynchronously with each other.

10. The device of claim 9, wherein the high, middle, and low dual-tail samplers are configured to operate at least partially asynchronously by one of the high, middle, and low dual-tail samplers being clocked using a first clock phase and a remaining two of the high, middle, and low dual-tail samplers being clocked using a second clock phase complementary to the first clock phase.

11. The device of claim 9, wherein the high, middle, and low dual-tail samplers are configured to operate at least partially asynchronously by clock gating two of the high, middle, and low dual-tail samplers when the remaining sampler has a predetermined output.

12. The device of claim 11, wherein the remaining sampler comprises the high sampler.

13. The device of claim 9, wherein at least one of the high, middle, and low dual-tail samplers comprises:
a first stage comprising:
an input pair;
a cross-coupled load circuit;
a precharge device between drain nodes of input pair; and
at least one pass-gate switch between the input pair and the cross-coupled load circuit.

14. The device of claim 13, wherein the at least one pass-gate switch comprises a pair of complementary pass-gate switches.

15. The device of claim 13, wherein the cross-coupled load circuit is connected to drain nodes of the input pair rather than to output nodes of the first stage.

16. The device of claim 13, wherein the first stage comprises an amplification stage.

17. The device of claim 13, further comprising a precharge device connected between drain nodes of the input pair.

18. A system comprising:
an error receiver that receives a PAM 4 error signal, comprising:
a high dual-tail sampler, a middle dual-tail sampler, and a low dual-tail sampler, each of which receive the PAM 4 error signal, and each of which comprise:
a first stage comprising:
an input pair;
a cross-coupled load circuit;
a precharge device between drain nodes of the input pair; and
at least one pass-gate switch between the input pair and the cross-coupled load circuit; and
a thermometer-to-binary device that converts outputs of the high, middle, and low dual-tail samplers into a two-bit error code.

19. The system of claim 18, wherein one of the high, middle, and low dual-tail samplers is clocked using a first clock phase and a remaining two of the high, middle, and low dual-tail samplers is clocked using a second clock phase complementary to the first clock phase.

20. The system of claim 18, wherein:
a given output of a selected dual-tail sampler of the high, middle, and low dual-tail samplers maps to a given error class in the two-bit error code irrespective of signals from a remaining two dual-tail samplers; and
the two remaining dual-tail samplers are clock gated when the selected dual-tail sampler has the given output.
